(19) United States
(12) Patent Application Publication
(10) Pub. No.: US 2005/0179049 A1
(43) Pub. Date: Aug. 18, 2005

(54) Light emitting diode

(76) Inventor: Ying-Ming Ho, Taipei (TW)

Correspondence Address: LighTop Technology Co., Ltd., P.O. Box No. 6-57, Junghe, Taipei, 235, TW

(21) Appl. No.: 10/777,116

(22) Filed: Feb. 13, 2004

(51) Int. Cl. H01L 33/00

(52) U.S. Cl. 257/100

(57) ABSTRACT

A light emitting diode (LED) is a sealed and packaged structure for elevating heat dissipation efficiency of the LED; and is characterized that, a light emitting chip is placed at an area defined by fingers of the LED, and the light emitting diode has a lower portion thereof utilizing an inorganic material as a part of a sealed housing. According to the aforesaid structure, heat energy generated by the LED when a large electric current is inputted is rapidly conducted to an exterior via the inorganic material to offer all-round heat dissipation effects, thereby preventing the light emitting chip from damages caused by quantitative change due to high temperature as well as lengthening usage lifespan of the LED.

### BACKGROUND OF THE INVENTION

(a) Field of the Invention

The invention relates to a light emitting diode (LED), and more particularly, to an LED that is capable of rapidly dissipating heat generated to offer all-round heat dissipation effects, thereby preventing a light emitting chip therein from damages caused by quantitative change due to high temperature as well as lengthening usage lifespan of the LED.

(b) Description of the Prior Art

Referring to FIG. 5 showing a prior light emitting diode (LED), a light emitting chip 1 is adhered to a vessel of a rack 2, and transparent epoxy 61 is then utilizes to encapsulate the single light emitting chip 1 that is already bonded, such that a semi-spherical body with light condensing effects is formed above the light emitting chip 1 to focus light beams emitted toward a center. The above structure is a most common LED having a sealed housing using the epoxy 61.

It is a world trend to economize resources, and therefore, using high light emitting efficiency of LED, substantial electric power can be saved supposed LED takes place of conventional light sources. However, in order to have LED replace conventional light sources, it is essential that light intensity of LED be elevated. To elevate light intensity, an input power current must be increased. Once the input power current is increased, heat energy generated by the light emitting chip is enlarged as well. A unit area of a light emitting chip compared to that of a conventional light source is quite small, and thus accumulated heat energy per unit area of the light emitting chip is consequently much larger than that accumulated on a conventional light emitting chip. In addition, a prior LED using epoxy as a sealed housing offers rather limited heat dissipation effects. The reason behind is that epoxy has a thermal conductance of merely about 0.2 W/m° C. As a result, for that heat energy generated by the light emitting chip cannot be effectively conducted to an exterior of the sealed housing, a temperature of the light emitting chip is often remained at as high as 80 degrees Celsius, with light emitting efficiency being lowered and likely incurring damages of the LED due to quantitative change caused by high temperature.

### SUMMARY OF THE INVENTION

The primary object of the invention is to provide a light emitting diode (LED) capable of rapidly conducting heat energy generated by the LED to an exterior for offering all-round heat dissipation effects, thereby preventing a light emitting chip from damages caused by quantitative change due to high temperature as well as lengthening usage lifespan thereof.

To accomplish the aforesaid object, an LED according to the invention is a sealed structure capable of elevating heat dissipation efficiency of the LED; and is characterized that, a light emitting chip of the LED is placed at an area defined by fingers of the LED, and a lower portion of the light emitting diode is sealed and packaged by an inorganic material as a part of a sealed housing.

According to the aforesaid structure, heat energy generated by the LED when a large electric current is inputted is rapidly conducted to an exterior via the inorganic material to offer all-round heat dissipation effects, thereby preventing the light emitting chip from damages caused by quantitative change due to high temperature as well as lengthening usage lifespan of the LED.

### BRIEF DESCRIPTION OF THE DRAWINGS

FIG. 1 shows an elevational view according to the invention.

FIGS. 2, 3 and 4 shows elevational views illustrating individual packaging embodiments according to the invention.

FIG. 5 shows an elevational view of a prior light emitting diode (LED).

### DETAILED DESCRIPTION OF THE PREFERRED EMBODIMENTS

To better understand the structures, devices and characteristics of the invention, detailed descriptions of a preferred embodiment shall be given with the accompanying drawings below.

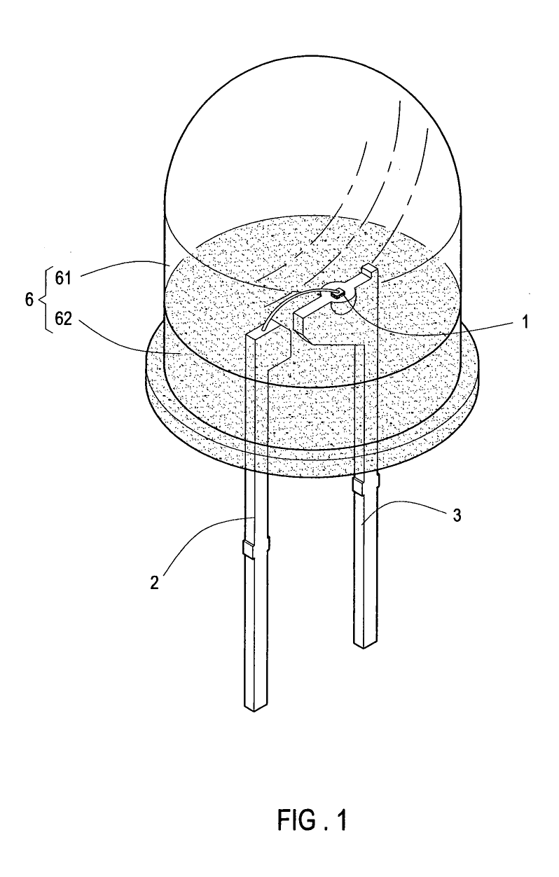

Referring to FIG. 1, a light emitting diode (LED) according to the invention comprises a light emitting chip 1, a positive finger 2, a negative finger 3 and a sealed housing 6. The light emitting chip 1 is disposed at the negative finger 3.

The invention is characterized that, the light emitting chip 1 has an upper portion thereof sealed and packaged by transparent epoxy 61, and a lower portion thereof sealed and packaged by an inorganic material 62 having a high thermal conductance coefficient.

The aforesaid inorganic material 62 may be silicon carbide (SiC) having a thermal conductance of 270 W/m° C., aluminum nitride (AlN) having a thermal conductance of 240 W/m° C., boron nitride (BN) having a thermal conductance of 600 W/m° C., and an artificial diamond having a thermal conductance of 2000 W/m° C.

According to the aforesaid structure, the LED may be formed using poured-mold means. Epoxy is first poured into a mold to have reached a position of the light emitting chip. When the epoxy is hardened, a thermosetting inorganic material is poured into the mold to have the inorganic material encapsulate the positive and negative fingers. When the thermosetting inorganic material is cooled and hardened, the poured-mold LED is taken out of the mold for packaging.

According to the aforementioned descriptions, for that the positive finger 2 and the negative finger 3 of the LED structure are in contact with the inorganic material 62, heat energy generated by the light emitting chip 1 is directly conducted to an exterior of the LED via the positive finger 2, the negative finger 3 and the inorganic material 62, thereby achieving rapid heat dissipation effects for preventing the light emitting chip 1 from damages caused by quantitative change due to high temperature.

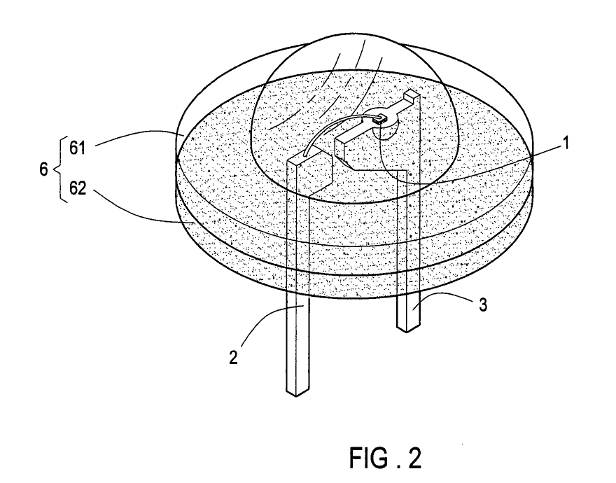

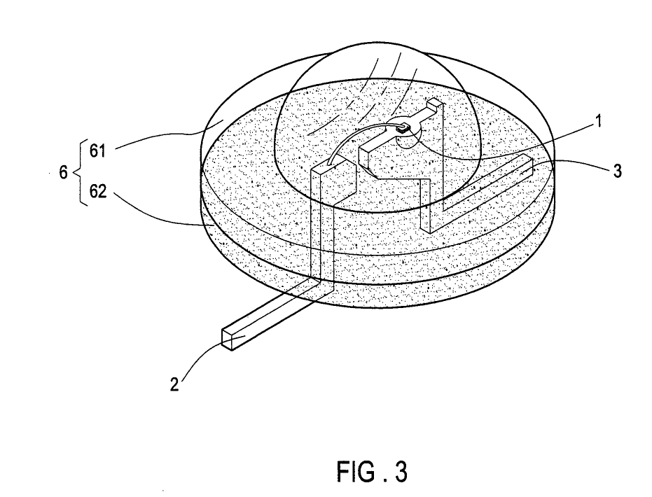

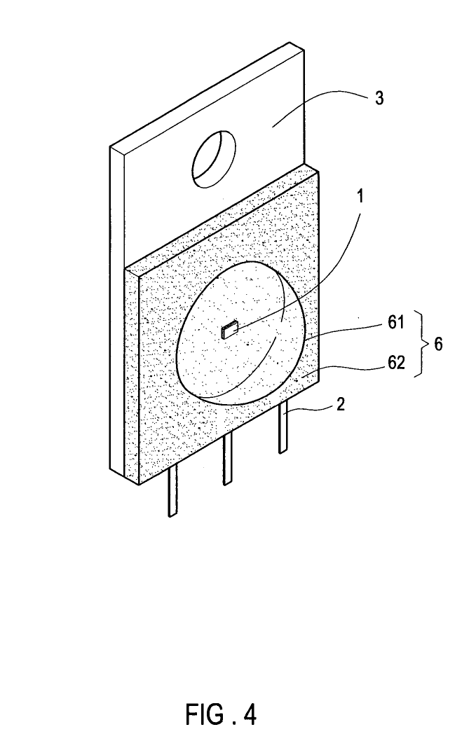

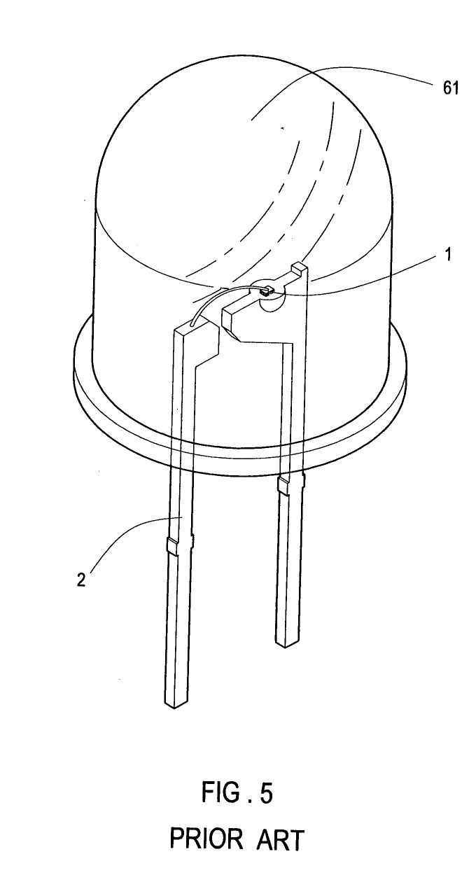

Referring to FIGS. 2, 3 and 4, the light emitting diode may also be sealed and packaged using various packaging methods.

Furthermore, the LED according to the invention may be formed by stamped-mold means. The inorganic material 62 and the epoxy 62 are first mixed and then stamped to form a structure.

Conclusive from the above, the LED according to the invention is capable of rapid heat dissipation for preventing the light emitting chip from damages caused by quantitative change due to high temperature. It is of course to be understood that the embodiment described herein is merely illustrative of the principles of the invention and that a wide variety of modifications thereto may be effected by persons skilled in the art without departing from the spirit and scope of the invention as set forth in the following claims.

1. A light emitting diode (LED) comprising a light emitting chip, a positive finger, a negative finger and a sealed housing, wherein the light emitting chip is disposed at the negative finger; and being characterized that, the sealed housing at an exterior of the light emitting chip has an upper portion thereof as transparent epoxy and a lower portion thereof as an inorganic material having a high thermal conductance coefficient.

2. The LED in accordance with claim 1, wherein the inorganic material is silicon carbide (SiC).

3. The LED in accordance with claim 1, wherein the inorganic material is aluminum nitride (AlN).

4. The LED in accordance with claim 1, wherein the inorganic material is beryllium oxide (BeO).

5. The LED in accordance with claim 1, wherein the inorganic material is boron nitride (BN).

6. The LED in accordance with claim 1, wherein the inorganic material is an artificial diamond.
